(19) United States
(12) Patent Application Publication
(10) Pub. No.: US 2025/0029850 A1
(43) Pub. Date: Jan. 23, 2025

(54) METHODS OF ANALYZING UNIFORMITY, AND RELATED APPARATUS AND SYSTEMS, FOR SEMICONDUCTOR MANUFACTURING

(71) Applicant: Applied Materials, Inc., Santa Clara, CA (US)

(72) Inventors: Kim Ramkumar VELLORE, San Jose, CA (US); Tetsuya ISHIKAWA, San Jose, CA (US); Ala MORADIAN, Sunnyvale, CA (US)

(21) Appl. No.: 18/224,996

(22) Filed: Jul. 21, 2023

(51) Int. Cl. H01L 21/67; H01L 21/66; H01L 21/687

(52) U.S. Cl. CPC H01L 21/67253; H01L 21/67248; H01L 21/68764; H01L 22/12; H01L 22/26; H01L 22/34

(57) ABSTRACT

The present disclosure relates to methods of analyzing uniformity for substrate processing, and related apparatus and systems, for semiconductor manufacturing. In one or more embodiments, a non-uniformity is indicated, and the non-uniformity is a temperature non-uniformity and/or a physical non-uniformity. In one or more embodiments, a signal profile is accepted or rejected. In one or more embodiments, a method of analyzing uniformity for substrate processing applicable for semiconductor manufacturing includes heating an internal volume of a processing chamber using a target value. The method includes rotating a substrate support, and scanning, while rotating the substrate support, a sensor across one or more sections to take a plurality of readings. The method includes generating a signal profile including the plurality of readings, and analyzing the signal profile by comparing the signal profile to a range.

### BACKGROUND

### Field

The present disclosure relates to methods of analyzing uniformity for substrate processing, and related apparatus and systems, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate. For example, temperature non-uniformities and/or physical non-uniformities can affect deposition uniformity. As an example, the temperature of the substrate and/or temperature(s) of processing chamber component(s) can affect deposition uniformity. As another example, stress and/or warpage of the substrate can cause temperature non-uniformities and/or deposition non-uniformities. Stress and/or warpage can also cause performance hindrances, and can result in breakage.

It can be difficult to monitor for non-uniformities, and non-uniformities can result in processing delays, substrate waste, and reduced throughput.

Therefore, a need exists for improved method, apparatus, and systems for analyzing uniformity.

### SUMMARY

The present disclosure relates to methods of analyzing uniformity for substrate processing, and related apparatus and systems, for semiconductor manufacturing. In one or more embodiments, a non-uniformity is indicated, and the non-uniformity is a temperature non-uniformity and/or a physical non-uniformity.

In one or more embodiments, a method of analyzing uniformity for substrate processing applicable for semiconductor manufacturing includes heating an internal volume of a processing chamber using a target value. The method includes rotating a substrate support, and scanning, while rotating the substrate support, a sensor across one or more sections to take a plurality of readings. The method includes generating a signal profile including the plurality of readings, and analyzing the signal profile by comparing the signal profile to a range.

In one or more embodiments, a non-transitory computer readable medium applicable for semiconductor manufacturing includes instructions that when executed cause a plurality of operations to be conducted. The plurality of operations include analyzing a signal profile by comparing the signal profile to a range. The range is less than 10% of a target value. The analyzing includes identifying a signal difference in the signal profile, and determining if the signal difference is within or outside of the range. The plurality of operations include, if the signal difference is outside of the range, conducting one or more of: indicating a process non-uniformity, or rejecting the signal profile.

In one or more embodiments, a system for processing substrates and applicable for semiconductor manufacturing includes a chamber body that includes one or more sidewalls, and a window. The one or more sidewalls and the window at least partially define an internal volume. The system includes one or more heat sources configured to heat the internal volume, a substrate support disposed in the internal volume, and a sensor configured to sense parameters in the internal volume. The system includes a controller including instructions that, when executed, cause a plurality of operations to be conducted. The plurality of operations include generating a signal profile, the signal profile including a plurality of readings. The plurality of operations include analyzing the signal profile by comparing the signal profile to a range. The range is less than 10% of a target value. The analyzing includes identifying a signal difference in the signal profile, and determining if the signal difference is within or outside of the range. The plurality of operations include, if the signal difference is outside of the range, conducting one or more of: indicating a process non-uniformity, or rejecting the signal profile.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic side view of a uniformity profile across the substrate and/or the substrate support shown in FIG. 1, according to one or more embodiments.

FIG. 3 is a schematic block diagram view of a method of analyzing uniformity for substrate processing applicable for semiconductor manufacturing, according to one or more embodiments.

FIG. 4 is a schematic block diagram view of a method of analyzing uniformity for substrate processing applicable for semiconductor manufacturing, according to one or more embodiments.

FIG. 5 is a schematic flow diagram view of an exemplary implementation of the method shown in FIG. 3 and the method shown in FIG. 4, according to one or more embodiments.

FIG. 6 is a schematic top view of the processing chamber during operations of the method shown in FIG. 3, according to one or more embodiments.

FIG. 7 is a schematic graphical view of an exemplary signal profile created using the implementation shown in FIG. 6, according to one or more embodiments.

FIG. 8 is a schematic top view of the processing chamber during operations of the method shown in FIG. 3, according to one or more embodiments.

FIG. 9 is a schematic graphical view of an exemplary first signal profile and second signal profile created using the implementation shown in FIG. 8, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to methods of analyzing uniformity for substrate processing, and related apparatus and systems, for semiconductor manufacturing. In one or more embodiments, a non-uniformity is indicated, and the non-uniformity is a temperature non-uniformity and/or a physical non-uniformity. In one or more embodiments, a signal profile is accepted or rejected.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

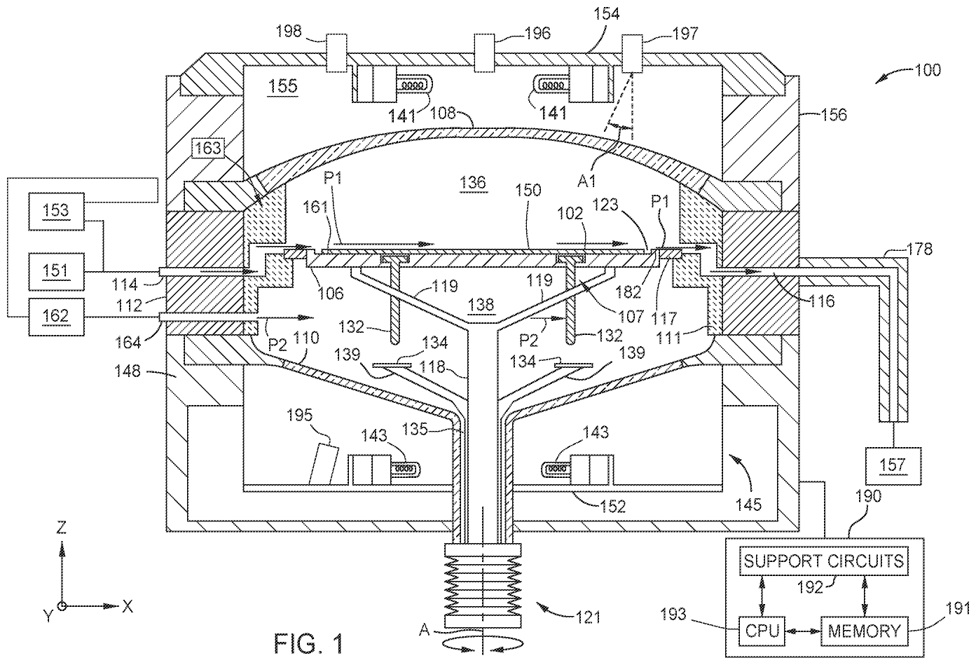

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz.

An upper volume 136 and a purge volume 138 are formed between the upper window 108 and the lower window 110. The upper volume 136 and the purge volume 138 are part of an internal volume defined at least partially by the upper window 108, the lower window 110, and one or more liners 111, 163. In one or more embodiments, the upper volume 136 is a processing volume.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phosphine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the upper volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the upper volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the upper volume 136.

The processing system includes one or more sensors 195, 196, 197, 198 (e.g., temperature sensors) configured to measure parameter(s) (e.g., temperature(s)) within the processing chamber 100. In one or more embodiments, the one or more temperature sensors 195, 196, 197, 198 include a central sensor 196 and one or more outer sensors 195, 197, 198. A controller 190 (described below) can control the one or more sensors 195, 196, 197, 198, and can conduct method(s) analyzing uniformity of substrate processing using at least one of the one or more sensors 195, 196, 197, 198. In one or more embodiments, the one or more sensors 195, 196, 197, 198 each include a pyrometer, such as a pyrometer that includes a silicon sensor. In one or more embodiments, each sensor 195, 196, 197, 198 is an optical sensor, such as an optical pyrometer. The present disclosure contemplates that sensors other than pyrometers may be used, and/or one or more of the sensors 195, 196, 197, 198 can measure properties other than temperature.

In one or more embodiments, the one or more sensors 195, 196, 197, 198 include one or more upper sensors 196, 197, 198 disposed above the substrate 102 and adjacent the lid 154, and one or more lower sensors 195 disposed below the substrate 102 and adjacent the floor 152. The present disclosure contemplates that at least one of the one or more lower sensors 195 can be vertically aligned below at least one of the upper sensors 196, 196, 197 (such as outer sensor 197).

Each sensor 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensors 195, 196, 197, 198. In one or more embodiments, the process chamber 100 includes one or more additional sensors, in addition to the sensors 195, 196, 197, 198. In one or more embodiments, the process chamber 100 may include sensors disposed at different locations and/or with different orientations than the illustrated sensors 195, 196, 197, 198.

As shown, a controller 190 is in communication with the processing chamber 100 and is used to control processes and methods, such as the operations of the methods described herein.

The controller 190 is configured to receive data or input as sensor readings from sensor(s) (such as one or more of the sensors 195, 196, 197, 198). The sensors can include, for example: sensors that monitor growth of layer(s) on the substrate 102; and/or sensors that monitor temperatures of the substrate 102, the substrate support 106, and/or the liners 111, 163. The controller 190 is equipped with or in communication with a system model of the processing chamber 100. The system model includes a heating model, a temperature uniformity model, a film uniformity model, a film deposition rate model, a coating model, a rotational position model, and/or a gas flow model. The system model is a program configured to estimate parameters (such as a signal profile (e.g., a temperature profile) of the substrate 102 and/or the substrate support 106, a gas flow rate, a gas pressure, a rotational position of component(s), a heating profile, a coating condition, and/or a cleaning condition) within the processing chamber 100 throughout a deposition operation and/or a cleaning operation. The controller 190 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor heating, generate a signal profile (e.g., a temperature profile), indicate a process non-uniformity, accept or reject the signal profile, estimate an optimized parameter, adjust the one or more sensors, generate an alert on a display, halt a deposition operation, initiate a chamber downtime period, delay a subsequent iteration of the deposition operation, initiate a cleaning operation, halt the cleaning operation, adjust a heating power, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

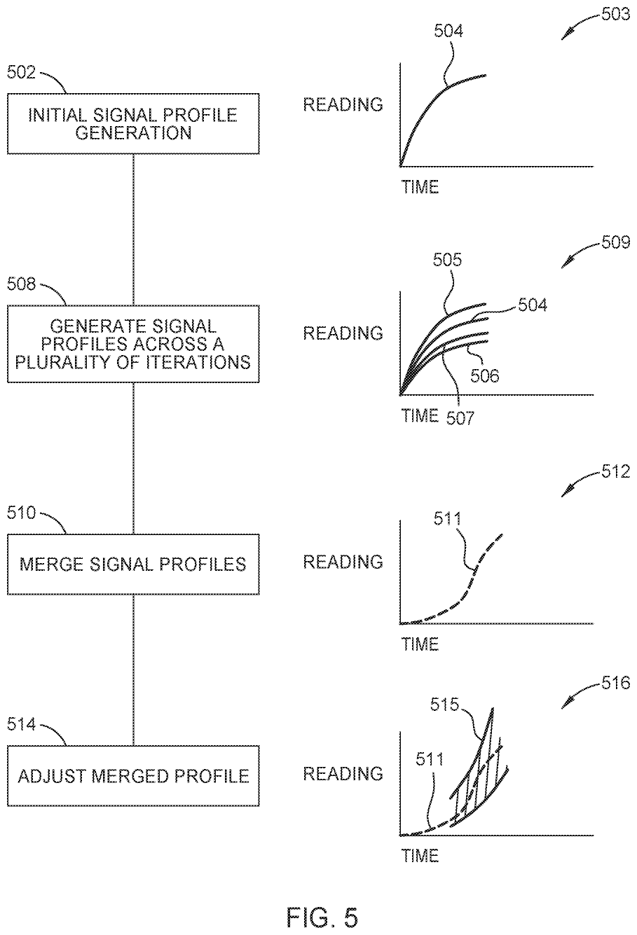

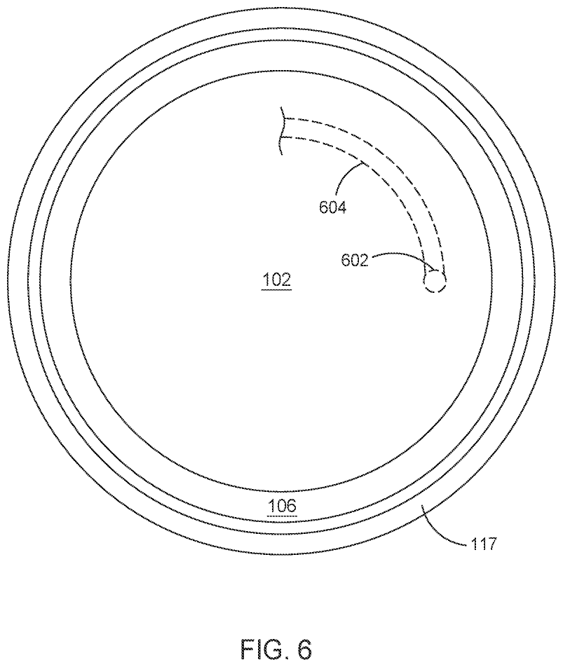

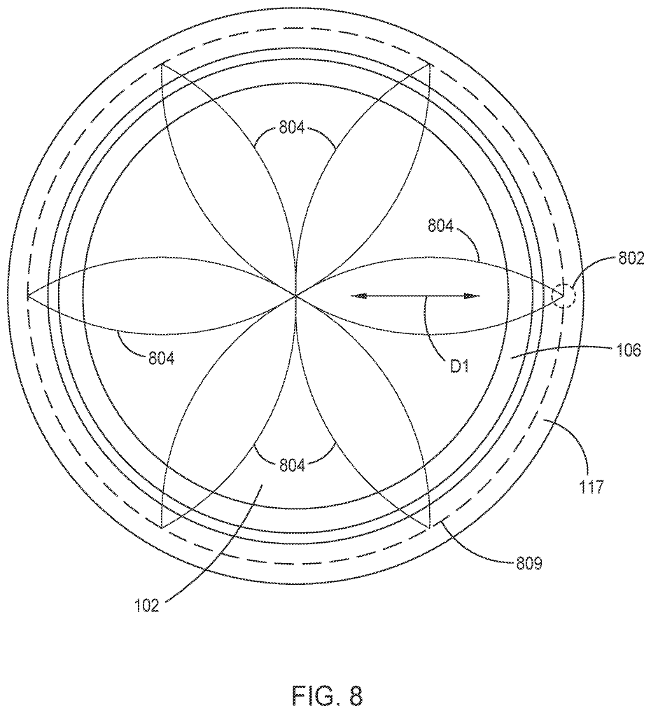

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., target value(s), reading(s), signal difference(s), signal profile(s), range(s) and/or training range(s) with which the signal difference(s) are compared, a heating power applied to the heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of operations of: method 300, method 400, FIG. 5, FIG. 6, and/or FIG. 8 to be conducted in relation to the processing chamber 100. The controller 190 and the processing chamber 100 are at least part of a system for processing substrates.

The various operations described herein (such as the operations of method 300, method 400, FIG. 5, FIG. 6, and/or FIG. 8) can be conducted automatically using the controller 190, or can be conducted automatically or manually with certain operations conducted by a user.

In one or more embodiments, the controller 190 includes a mass storage device, an input control unit, and a display unit. The controller 190 can monitor the temperature of the substrate 102, the temperature of the substrate support 106, the process gas flow, and/or the purge gas flow. In one or more embodiments, the controller 190 includes multiple controllers 190, such that the stored readings and calculations and the system model are stored within a separate controller from the controller 190 which controls the operations of the processing chamber 100. In one or more embodiments, all of the system model and the stored readings and calculations are saved within the controller 190.

The controller 190 is configured to control the deposition, the cleaning, the rotational position, the heating, and gas flow through the processing chamber 100 by providing an output to the controls for the sensors 195, 196, 197, 198, the upper heat sources 141, the lower heat sources 143, the process gas source 151, the purge gas source 162, the motion assembly 121, and/or the exhaust pump 157.

The controller 190 is configured to adjust the output to the controls based on the sensor readings, the system model, and the stored readings and calculations. The controller 190 includes embedded software and a compensation algorithm to calibrate measurements. The controller 190 can include one or more machine learning algorithms and/or artificial intelligence algorithms that estimate optimized parameters for the uniformity analysis operations, the deposition operations, and/or the cleaning operations.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100 and/or method(s) (such as the method(s) 300, 400) relative to other aspects of the process chamber 100 and/or method(s) (such as the method(s) 300, 400). The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100 and/or method(s) (such as the method(s) 300, 400). For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method(s) (such as the method(s) 300, 400). The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, optimized parameters such as target value(s), reading(s), signal difference(s), signal profile(s), range(s) and/or training range(s) with which the signal difference(s) are compared, a heating power applied to the heat sources 141, 143, a cleaning recipe, and/or a processing recipe.

In one or more embodiments, the controller 190 automatically conducts the operations described herein without the use of one or more machine learning algorithms and/or artificial intelligence algorithms. In one or more embodiments, the controller 190 compares measurements (such as readings and/or signal differences) to data in a look-up table and/or a library to indicate a process non-uniformity and/or to accept or reject signal profile(s). The controller 190 can stored measurements as data in the look-up table and/or the library.

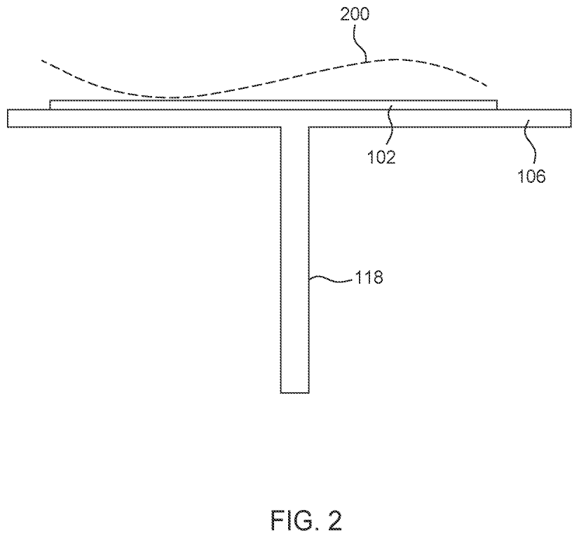

FIG. 2 is a schematic side view of a uniformity profile 200 across the substrate 102 and/or the substrate support 106 shown in FIG. 1, according to one or more embodiments. As shown the uniformity profile 200 can include one or more process non-uniformities across a direction that is parallel to the diameter of the substrate 102 and/or the diameter of the substrate support 106.

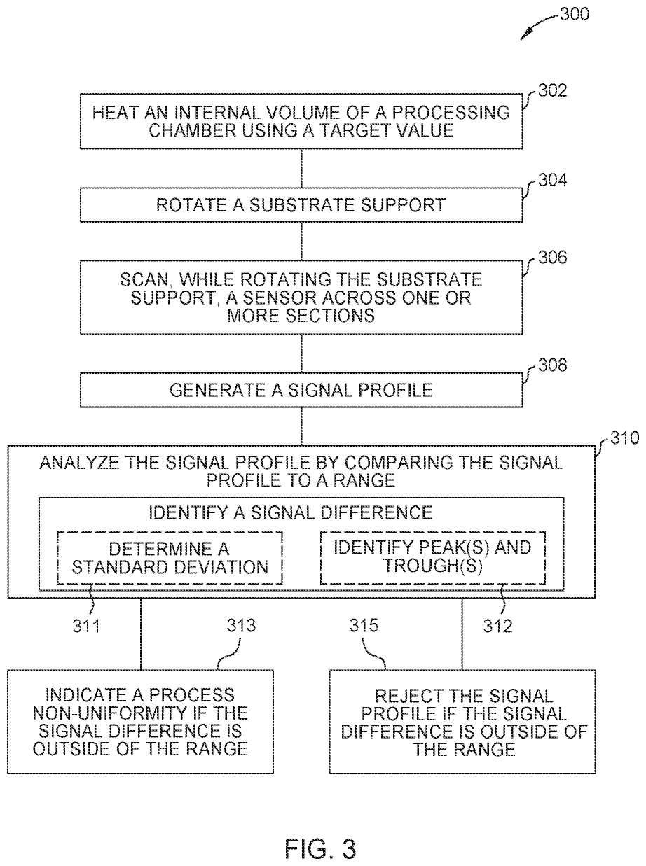

FIG. 3 is a schematic block diagram view of a method 300 of analyzing uniformity for substrate processing applicable for semiconductor manufacturing, according to one or more embodiments.

Operation 302 of the method 300 includes heating an internal volume of a processing chamber using a target value. The target value can be pre-set, for example, by a user and/or by the controller 190. In one or more embodiments, the target value described herein is a target temperature. In one or more embodiments, the target temperature is within a range of 400 degrees Celsius to 550 degrees Celsius. In one or more embodiments, the target temperature is within a range of 700 degrees Celsius to 800 degrees Celsius.

Operation 304 includes rotating a substrate support.

Operation 306 includes scanning, while rotating the substrate support, a sensor across one or more sections to take a plurality of readings. In one or more embodiments, the sensor is a temperature sensor and the plurality of readings are a plurality of temperature readings. In one or more embodiments, the one or more sections are disposed along the substrate support or along a substrate positioned on the substrate support. The one or more sections extend azimuthally and are disposed at one or more radial locations. In one or more embodiments, the plurality of readings are taken at a sampling frequency while the substrate support is rotated at a rotation speed. The rotation speed is a ratio of the sampling frequency. In one or more embodiments, the ratio is less than 0.1. In one or more embodiments, the ratio is 0.015 or less. In one or more embodiments, the ratio is 0.010 or less, such as within a range of 0.0025 to 0.0075. The sampling frequency is within a range of 1 Hz to 10 KHz. In one or more embodiments, the sampling frequency is within a range of 90 Hz to 110 Hz, such as about 100 Hz. In one or more embodiments, the rotation speed is within a range of 0.50 cycles (e.g., rotations) per second to 0.55 cycles per second, such as about 32 cycles per minute. The readings are taken at a reading rate of at least 100 data points per revolution of the rotation of the substrate support. In one or more embodiments, the reading rate is at least 200 data points per revolution, for example at least 400 data points per revolution, such as 600 or more data points per revolution. Other values are contemplated for the rotation speed, the sampling frequency, the ratio, and/or the reading rate.

Operation 308 includes generating a signal profile including the plurality of readings. In one or more embodiments, the signal profile is a temperature profile.

Operation 310 includes analyzing the signal profile by comparing the signal profile to a range. The analyzing includes identifying a signal difference in the signal profile, and determining if the signal difference is within or outside of the range. In one or more embodiments, the signal difference is a temperature difference.

The identifying of the signal difference includes (at optional operation 311) determining a standard deviation of the signal profile, and the signal difference is the standard deviation.

The identifying of the signal difference includes (at optional operation 312) identifying one or more peaks and one or more troughs of the signal profile. In one or more embodiments, the signal difference is a difference between one of the one or more peaks and an adjacent trough of the one or more troughs. The adjacent trough can be within one revolution of the one of the one or more peaks. In one or more embodiments, the signal difference is a difference between a highest peak of the one or more peaks and a lowest trough of the one or more troughs.

In one or more embodiments, a field of view of the sensor is moved during the scanning of operation 306 such that the one or more sections extend radially, and the range is less than 10% of the target value of operation 302. In one or more embodiments, the range is 8% or lower of the target value, such as 5% or lower of the target value.

In one or more embodiments, the field of view of the sensor is substantially stationary during the scanning of operation 306 such that the one or more sections extend arcuately (e.g., azimuthally, such as circumferentially), and the range is less than 2.5% of the target value of operation 302. In one or more embodiments, the range is less than 1.0% of the target value, such as 0.8% or lower of the target value, for example 0.5% or less of the target value.

Operation 313 includes indicating a process non-uniformity if the signal difference is outside of the range. The process non-uniformity can indicate, for example, a non-uniformity of the substrate (such as the substrate 102), and/or the substrate support (such as the substrate support 106). The process non-uniformity can be a non-uniformity in temperature or material (such as component thickness of the substrate and/or the substrate support, coating thickness (e.g., of silicon carbide coated on graphite or reacted material from process gases) of the substrate support, machining defects of the substrate support, and/or surface roughness of the substrate support). The non-uniformity can be caused by insufficient and/or non-uniform cleaning. The process non-uniformity can be a non-uniformity in substrate shape caused by warpage (e.g., bowing). Warpage can be caused, for example, by non-uniform heating and/or properties of the substrate. The present disclosure contemplates that the process non-uniformity can indicate other non-uniformities. The non-uniformity can be caused, for example, by component placement (such as non-uniformities in the distances between the lift pins 132 and the substrate 102 and/or misalignment of the substrate 102 relative to a center of the substrate support 106). The non-uniformity can be caused, for example, by component erosion (such as erosion of the substrate support 106, such as erosion of a coating on the substrate support 106), and/or component reaction (such as reaction of process gases with the substrate support 106). The non-uniformity can be caused, for example, by process drift (such as heat source drift).

The method 300 can use the process non-uniformity (indicated at operation 313) to cause an action to be conducted (e.g., automatically or using a generated alert to a user). The action can include, for example, initiation of chamber downtime, replacement of the substrate support, adjustment of process recipe (such as the target value, e.g., the target temperature) and/or heating power, and/or flagging the substrate for re-processing (such as re-deposition).

In addition to or in place of operation 313, the method 300 can include—at operation 315—rejecting the signal profile if the signal difference is outside of the range. As discussed below, the signal profile can be rejected in relation to a training model.

The information of the method 300 (such as the target value(s), the reading(s), the signal difference(s), the signal profile(s), and/or the range(s)) can be stored and tracked as data. In one or more embodiments, the data is analyzed and/or compared using averages, derivatives, modeling, imaging, and/or with other data analysis techniques. As an example, one or more optical sensors can capture images, and the intensity of the images can be analyzed for detection of the readings (e.g., the temperature readings).

The present disclosure contemplates that methods described herein (such as the method 300) can be conducted during a deposition operation and/or before and/or after a deposition operation. For example, the method 300 can conducted during a simulation process without the substrate 102 present in the chamber 100.

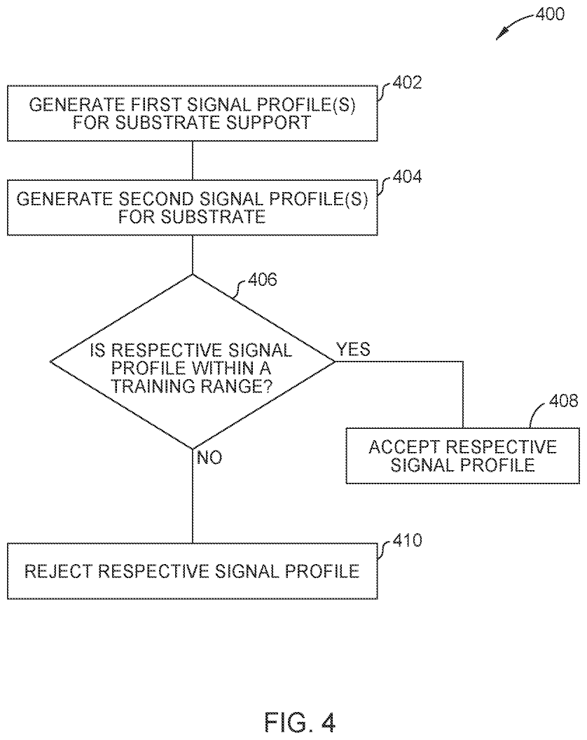

FIG. 4 is a schematic block diagram view of a method 400 of analyzing uniformity for substrate processing applicable for semiconductor manufacturing, according to one or more embodiments. In one or more embodiments, the method 400 is part of a supervised machine learning algorithm that facilitates training a system (e.g., of the controller 190).

Operation 402 includes generating one or more first signal profiles for the substrate support. In one or more embodiments, the one or more first signal profiles are one or more first temperature profiles. Operation 402 can include conducting operations 306 and 308 of the method 300, and the one or more sections of operation 306 are along the substrate support. Operation 402 can include, for example use of the lower sensor 195.

Operation 404 includes generating one or more second signal profiles for the substrate. In one or more embodiments, the one or more second signal profiles are one or more second temperature profiles. Operation 404 can include conducting operations 306 and 308 of the method 300, and the one or more sections of operation 306 are along the substrate. Operation 402 can include, for example use of the one or more upper sensors 196, 197, 198. The one or more sections of operation 404 are disposed at the same one or more radial locations as the one or more sections of operation 402.

Operation 406 includes analyzing the one or more first signal profiles and the one or more second signal profiles by comparing the one or more first signal profiles and the one or more second signal profiles to a training range. The training range can be the same as or different than (such as larger than) the range of operation 310. Operation 406 can include one or more aspects of operation 310 of the method 300.

If a respective signal difference (e.g., temperature difference) of each of the first and second signal profiles is within the training range, then the respective signal profile is accepted at operation 408. If accepted, then the respective signal profile can be included as part of the training data for the training model, and can be included, for example, in the look-up table and/or library. In one or more embodiments, the accepting of operation 408 includes labeling the respective profile as accepted in the training model. The accepted label can be stored, for example, in the look-up table and/or library. The accepted label can apply, for example, to one or more corresponding components (such as the substrate and/or substrate support corresponding to the respective signal profile).

If the respective signal difference of each of the first and second signal profiles is outside of the training range, then the respective signal profile is rejected at operation 410. If rejected, then the respective signal profile can be omitted from the training data for the training model, and can be omitted, for example, from the look-up table and/or library. In one or more embodiments, the rejecting of operation 410 includes labeling the respective profile as rejected in the training model. The rejected label can be stored, for example, in the look-up table and/or library. The rejected label can apply, for example, to one or more corresponding components (such as the substrate and/or substrate support corresponding to the respective signal profile).

In one or more embodiments, the one or more first signal profiles and the one or more second signal profiles are analyzed at operation 406 without first being merged. In one or more embodiments, the one or more first signal profiles and the one or more second signal profiles (e.g., that were generated using readings (for example, temperature readings) that were simultaneously collected) are merged into one or more merged profiles that are analyzed at operation 406 and then accepted and/or rejected according to operation 408 and/or operation 410.

The present disclosure contemplates that the first signal profiles of the substrate support and the second signal profiles of the substrate can be compared to each other. For example, when a substrate is placed on a substrate support, a first signal profile (e.g., first temperature profile) is generated for the substrate support and a second signal profile (e.g., second temperature profile) is generated for the substrate. An increase (e.g., a temperature increase) in the first signal profile of the substrate support and a decrease (e.g., a temperature decrease) in the second signal profile of the substrate, when occurring of area(s) corresponding to the substrate, can indicate that the substrate is warped (e.g., bowed) when placed on the substrate support, and the areas(s) are the area(s) where the substrate is spaced from the substrate support. Similarly, a decrease (e.g., a temperature decrease) in the first signal profile of the substrate support and an increase (e.g., a temperature increase) in the second signal profile of the substrate, when occurring of area(s) corresponding to the substrate, can indicate that the substrate is warped (e.g., bowed) when placed on the substrate support, and the areas(s) are the area(s) where the substrate contacts the substrate support.

The present disclosure contemplates that the training model for training the system and/or the methods described herein can involve film thickness readings and associated film thickness profiles that are generated. The film thickness readings can be taken during processing and/or after processing. The film thickness profile(s) can be analyzed in place of the temperature profile(s) described above, or the film thickness profile(s) can be merged with the temperature profile(s) described above such that data at the same locations along the substrate(s) are merged (e.g., averaged). The present disclosure contemplates that the training model for training the system and/or the methods described herein can be at least partially unsupervised. For example, the training model can account for film thickness profile(s) that are measured on substrate(s) after the substrate(s) are processed.

The present disclosure contemplates that the readings described herein can be analyzed-without units-before the readings are correlated to measurements having certain units. For example, the readings taken at operation 306 can be unit-less values and/or can be used to generate the signal profile (at operation 308) and analyze the signal profile (at operation 310) before the readings are correlated (using an emissivity of the substrate and/or the substrate support) to temperature measurements having units in, for example, Celsius or Fahrenheit. For example, the readings can be a measured intensity.

FIG. 5 is a schematic flow diagram view of an exemplary implementation of the method 300 shown in FIG. 3 and the method 400 shown in FIG. 4, according to one or more embodiments.

Operation 502 includes an initial signal profile (e.g., initial temperature profile) generation using one or more sensors (e.g., temperature sensors), and graph 503 shows part of a signal profile 504 (e.g., temperature profile) of readings (e.g., temperature readings) versus time using data collected during the initial signal profile generation. The time can be the time it takes for the one or more sensors to scan across the one or more sections. Conduction of operation 502 can include, for example, conducting operations 302, 304, 306, and 308 of the method 300.

Operation 508 includes generating by conducting operations 306 and 308 of the method 300 one or more additional times to generate additional signal profiles 505-507 (e.g., temperature profiles) across a plurality of iterations shown in graph 509. Parts of the signal profiles 505-507 are shown in the graph 509. For example, a more complete showing of the signal profiles 505-507 can include sinusoidal patterns. The iterations can be, for example, a plurality of target values (e.g., target temperatures), a plurality of radial locations for the one or more sections, a plurality of deposition operations (which can be conducted across a plurality of substrates), a plurality of substrate supports (with which a plurality of deposition operations can be conducted), and/or a plurality of components (such as the substrate 102 and the substrate support 106) for the one or more sections.

Each signal profile 504-507 corresponds to one of the plurality of iterations. If the iterations are target temperatures, the target temperatures can be achieved by a plurality of different bias power levels applied to the heat sources 141, 143. The signal profiles 504-507 and/or the associated readings (e.g., temperature readings) can be stored (e.g., in a library in the memory). The signal profiles 504-507 can be generated at different times (such as on different days) and can include process drift (such as sensor, heater drift, and/or substrate drift (for example from erosion).

Operation 510 includes merging the signal profiles 504-507 (which can be stored in the library in the memory) to create a merged profile 511 shown in graph 512 (part of the merged profile 511 is shown in the graph 512). The merged profile 511 can be analyzed at operation 310 and can be used to determine if a process non-uniformity is to be indicated. The merging can include averaging values along the signal profiles 504-507 (which can be line-fitted), and the averaging can include weighted averaging.

Operation 514 adjusting the merged profile 511 using adjustment fields 515, as shown in graph 516. The adjustment fields 515 can be calculated and applied using a model, such as a model that includes one or more machine learning and/or artificial intelligence algorithms. The model can use other measurements, such as film thickness measurements conducted on processed substrates and/or substrates being processed to determine film uniformities and/or film deposition rates.

FIG. 6 is a schematic top view of the processing chamber 100 during operations 302, 304, and 306 of the method 300 shown in FIG. 3, according to one or more embodiments.

The substrate support 106 is rotated such that a field of view 602 of sensor 197 is scanned across one or more sections 604 of the substrate 102, and/or the substrate support 106. The field of view 602 is substantially stationary during the scanning such that the one or more sections 604 extend arcuately (e.g., azimuthally, such as circumferentially). The substrate support 106 can make one or more complete revolutions such that the one or more sections 604 can make a complete ring, for example.

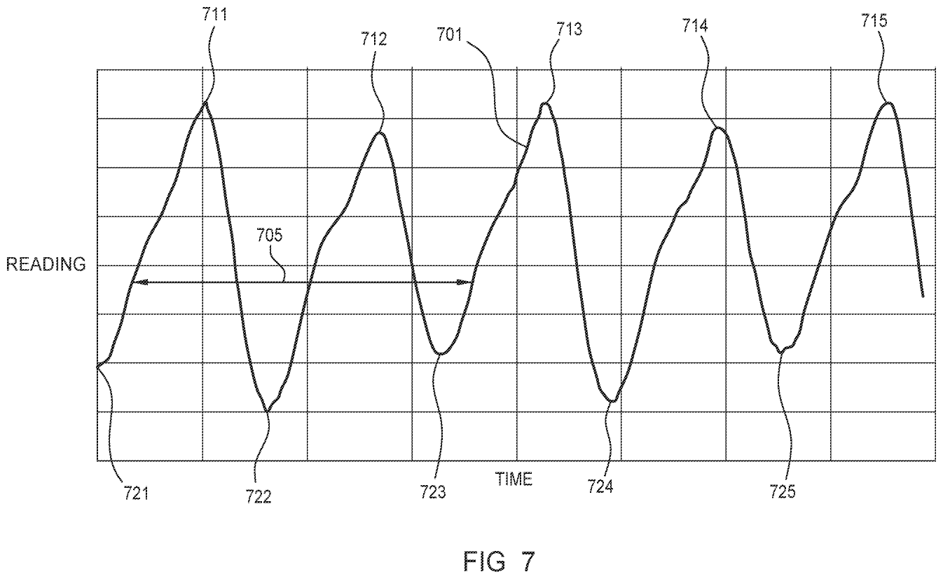

FIG. 7 is a schematic graphical view of an exemplary signal profile 701 created using the implementation shown in FIG. 6, according to one or more embodiments.

The signal profile 701 (e.g., a temperature profile) includes one or more peaks 711-715 and one or more troughs 721-725. As discussed above, analyzing the signal profile 701 can include identifying a highest peak 711 and a lowest trough 722. In one or more embodiments, the highest peak 711 indicates a largest warpage (e.g., bow) of a substrate and/or the lowest trough 722 indicates a contact point of the substrate with the substrate support. In one or more embodiments, the highest peak 711 can indicate a contact point of the substrate with the substrate support and/or the lowest trough 722 can indicate a largest warpage (e.g., bow) of the substrate.

Analyzing the signal profile 701 can include taking a standard deviation of the signal profile 701 (e.g., by taking a standard deviation under the signal profile 701). Arrow 705 indicates one complete revolution of the substrate support 106.

FIG. 8 is a schematic top view of the processing chamber 100 during operations 302, 304, and 306 of the method 300 shown in FIG. 3, according to one or more embodiments.

The substrate support 106 is rotated such that a field of view 802 of sensor 197 is scanned across one or more sections 804 of the substrate 102, and/or the substrate support 106. The field of view 802 is moved (e.g., linearly, such as radially along direction D1 relative to a center of the substrate support 106) during the scanning such that the one or more sections 804 extend radially (e.g., in addition to azimuthally). In one or more embodiments, the field of view 802 is scanned at least partially between a center of the substrate support 106 and an outer radius 809. The substrate support 106 can make one or more complete revolutions such that the one or more sections 804 can make the shapes of lobes (as shown in FIG. 8), for example. In one or more embodiments, the field of view 802 is moved by pivoting the sensor 197 by a plurality of angular increments A1 (shown in FIG. 1). The sensor 197 can be pivoted by the angular increment A1 between collected data points. In one or more embodiments, the angular increment A1 is less than 5 degrees, such as about 1.8 degrees, between the data points. In one or more embodiments, the pivoting causes a pitch between collected data points. The pitch is less than 25 mm, such as about 10 mm.

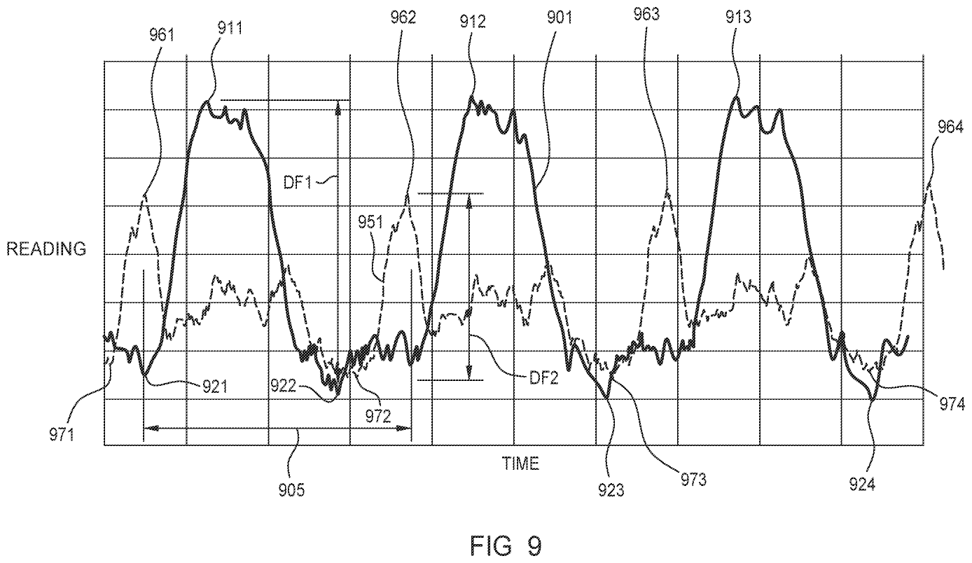

FIG. 9 is a schematic graphical view of an exemplary first signal profile 901 and second signal profile 951 created using the implementation shown in FIG. 8, according to one or more embodiments. In one or more embodiments, the first signal profile 901 is a first temperature profile and the second signal profile 951 is a second temperature profile.

The first signal profile 901 includes one or more peaks 911-913 and one or more troughs 921-924.

The second signal profile 951 includes one or more peaks 961-964 and one or more troughs 971-974.

Arrow 905 indicates one complete revolution of the substrate support for both the first signal profile 901 and the second signal profile 951.

The first signal profile 901 includes a first signal difference DF1 (e.g., a first temperature difference) and the second signal profile 951 includes a second signal difference DF2 (e.g., a second temperature difference). As shown the first signal difference DF1 is larger than the second signal difference DF2. The present disclosure contemplates that the second signal difference DF2 can be within the range and the first signal difference DF1 can be outside of the range. In one or more embodiments, the first signal difference DF1 is for a first substrate support and the second signal difference DF2 is for a second substrate support. In such an embodiment, the second substrate support can be accepted for further use and an alert can be generated for maintenance and/or replacement of the first substrate support.

Benefits of the present disclosure include accurate identification of non-uniformities; reduced, mitigated, or eliminated use of certain corrective measures (such as pre-heating); reduced inefficiencies; accurately initiating maintenance and/or replacement of chamber components (such as substrate supports); accurately and efficiently accounting for process drift (such as aging and wear of chamber components); accurately and efficiently accounting for substrate warpage (e.g., bowing); adjustability of parameters (such as temperatures, deposition uniformities, and/or deposition rates (e.g., in nm per minute)) across a variety of operation conditions (such as low rotation speeds, high pressures, and/or low flow rates); broader and/or more modular ranges of adjustability; and increased deposition uniformity and/or deposition rates. Benefits of the present disclosure also include reduced waste of substrates.

Benefits of the present disclosure further include increased component lifespan; reduced chamber downtime; reduced processing delays; and increased throughput. Benefits of the present disclosure also include enhanced deposition repeatability and/or cleaning repeatability.

It is contemplated that one or more aspects disclosed herein may be combined. As an example, one or more aspects, features, components, operations and/or properties of the processing chamber 100, the controller 190, the one or more sensors 195, 196, 197, 198, the method 300, the method 400, the exemplary implementation shown in FIG. 5, the exemplary implementation shown in FIG. 6, the signal profile 701, the exemplary implementation shown in FIG. 8, the first signal profile 901, and/or the second signal profile 951 may be combined. For example, the operations and/or parameters described in relation to FIGS. 5, 6, and/or 8 can be combined with the operations and/or the parameters of the method 300 and/or the method 400. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A method of analyzing uniformity for substrate processing applicable for semiconductor manufacturing, the method comprising:
heating an internal volume of a processing chamber using a target value;
rotating a substrate support;
scanning, while rotating the substrate support, a sensor across one or more sections to take a plurality of readings;
generating a signal profile including the plurality of readings; and
analyzing the signal profile by comparing the signal profile to a range.

2. The method of claim 1, wherein the analyzing comprises:
identifying a signal difference in the signal profile; and
determining if the signal difference is within or outside of the range.

3. The method of claim 2, wherein the identifying of the signal difference comprises identifying one or more peaks and one or more troughs of the signal profile.

4. The method of claim 2, further comprising, if the signal difference is outside of the range, conducting one or more of:
indicating a process non-uniformity; or
rejecting the signal profile.

5. The method of claim 2, wherein a field of view of the sensor is substantially stationary during the scanning such that the one or more sections extend azimuthally, and the range is less than 2.5% of the target value.

6. The method of claim 2, wherein a field of view of the sensor is moved during the scanning such that the one or more sections extend radially, and the range is less than 10% of the target value.

7. The method of claim 2, wherein the identifying of the signal difference comprises determining a standard deviation of the signal profile.

8. The method of claim 1, wherein:
the one or more sections are disposed along the substrate support or along a substrate positioned on the substrate support; and
the target value is a target temperature, the sensor is a temperature sensor, the plurality of readings are a plurality of temperature readings, the signal difference is a temperature difference, and the signal profile is a temperature profile.

9. A non-transitory computer readable medium applicable for semiconductor manufacturing, the non-transitory computer readable medium comprising instructions that when executed cause a plurality of operations to be conducted, the plurality of operations comprising:
analyzing a signal profile by comparing the signal profile to a range, the range is less than 10% of a target value, and the analyzing comprising:
identifying a signal difference in the signal profile, and
determining if the signal difference is within or outside of the range; and
if the signal difference is outside of the range, conducting one or more of:
indicating a process non-uniformity, or
rejecting the signal profile.

10. The non-transitory computer readable medium of claim 9, wherein the plurality of operations further comprise:
prior to the analyzing of the signal profile, generating the signal profile, the signal profile comprising a plurality of readings.

11. The non-transitory computer readable medium of claim 10, wherein the plurality of operations further comprise:
taking the plurality of readings at a sampling frequency while rotating a substrate support at a rotation speed, wherein the rotation speed is a ratio of the sampling frequency, and the ratio is less than 0.1.

12. The non-transitory computer readable medium of claim 9, wherein the identifying of the signal difference comprises identifying one or more peaks and one or more troughs of the signal profile.

13. The non-transitory computer readable medium of claim 12, wherein the signal difference is a difference between one of the one or more peaks and an adjacent trough of the one or more troughs.

14. The non-transitory computer readable medium of claim 13, wherein the adjacent trough is within one revolution of the one of the one or more peaks.

15. The non-transitory computer readable medium of claim 12, wherein the signal difference is a difference between a highest peak of the one or more peaks and a lowest trough of the one or more troughs.

16. The non-transitory computer readable medium of claim 9, wherein:
the range is less than 2.5% of the target value; and
the target value is a target temperature, the signal difference is a temperature difference, and the signal profile is a temperature profile.

17. The non-transitory computer readable medium of claim 9, wherein the identifying of the signal difference comprises determining a standard deviation of the signal profile.

18. A system for processing substrates and applicable for semiconductor manufacturing, the system comprising:
a chamber body comprising one or more sidewalls;
a window, the one or more sidewalls and the window at least partially defining an internal volume;
one or more heat sources configured to heat the internal volume;
a substrate support disposed in the internal volume;
a sensor configured to sense parameters in the internal volume; and
a controller comprising instructions that, when executed, cause a plurality of operations to be conducted, the plurality of operations comprising:
generating a signal profile, the signal profile comprising a plurality of readings,
analyzing the signal profile by comparing the signal profile to a range, the range is less than 10% of a target value, and the analyzing comprising:
identifying a signal difference in the signal profile, and
determining if the signal difference is within or outside of the range, and
if the signal difference is outside of the range, conducting one or more of:
indicating a process non-uniformity, or
rejecting the signal profile.

19. The system of claim 18, wherein the plurality of operations further comprising: taking the plurality of readings at a sampling frequency while rotating a substrate support at a rotation speed, wherein the rotation speed is a ratio of the sampling frequency, and the ratio is 0.015 or less.

20. The system of claim 18, wherein the identifying of the signal difference comprises determining a standard deviation of the signal profile.
